(19) United States
(12) Patent Application Publication
(10) Pub. No.: US 2024/0401230 A1
(43) Pub. Date: Dec. 5, 2024

(54) COMPOSITE SUBSTRATE AND MANUFACTURING METHOD THEREOF

(71) Applicant: ROHM CO., LTD., Kyoto (JP)

(72) Inventor: Keiju SATO, Kyoto (JP)

(73) Assignee: ROHM CO., LTD., Kyoto (JP)

(21) Appl. No.: 18/669,324

(22) Filed: May 20, 2024

(30) Foreign Application Priority Data
Jun. 5, 2023 (JP) 2023-092648

(51) Int. Cl. C30B 25/18; C30B 29/36

(52) U.S. Cl. CPC C30B 25/183; C30B 29/36

(57) ABSTRACT

The present disclosure provides a composite substrate. The composite substrate includes: a SiC single crystal substrate; and a carbon-containing layer, including a laminate of a reconstructed surface layer and a graphene layer or a graphene layer, which is disposed in contact with a surface of the SiC single crystal substrate. When observing by an atomic force microscope, a surface roughness (Ra) of the carbon-containing layer in contact with the SiC single crystal substrate is equal to or less than 1.0 nm in a square area of 2×2 μm².

### TECHNICAL FIELD

The present disclosure relates to a composite substrate and a manufacturing method thereof.

### BACKGROUND

Among methods for producing graphene, there is known a method of removing an oxide film formed by natural oxidation and covering the surface of a silicon carbide (SIC) single crystal substrate to expose the Si surface of the SiC single crystal substrate. The exposed SiC single crystal substrate is heated (thermally decomposed) in a vacuum or an inert gas such as argon (Ar). By heating in a vacuum or an inert gas such as argon (Ar), silicon (Si) sublimates and the remaining carbon (C) self-organizes, so that graphene is formed in a stacked manner on the SiC single crystal substrate.

### PRIOR ART DOCUMENTS

### Patent Document

[Patent Document 1] International Publication No. 2010/023934

### BRIEF DESCRIPTION OF THE DRAWINGS

FIG. 1 shows a cross-sectional view of a composite substrate according to the embodiment.

FIG. 2 shows a cross-sectional view of a composite substrate according to Modified example 1.

FIG. 3 shows a cross-sectional view of a composite substrate according to Modified example 2.

FIG. 4A is a cross-sectional view showing one step of the manufacturing steps of the composite substrate according to Modified example 2 (Part 1).

FIG. 4B is a cross-sectional view showing one step of the manufacturing steps of the composite substrate according to Modified example 2 (Part 2).

FIG. 4C is a cross-sectional view showing one step of the manufacturing steps of the composite substrate according to Modified example 2 (Part 3).

FIG. 4D is a cross-sectional view showing one step of the manufacturing steps of the composite substrate according to Modified example 2 (Part 4).

FIG. 5 is a cross-sectional view showing another step of the manufacturing steps of the composite substrate according to Modified example 2.

### DETAILED DESCRIPTION OF THE EMBODIMENTS

Next, embodiments will be described with reference to the accompanying drawings. In the description of the drawings described below, the same or similar symbols are assigned to the same or similar parts. The drawings are schematic. In addition, the embodiments shown below exemplify devices or methods for embodying technical ideas, and do not specify the materials, shapes, structures, arrangements, etc. of components. Various changes may be added to the embodiment.

The composite substrate of the present embodiment will be described using the accompanying drawings.

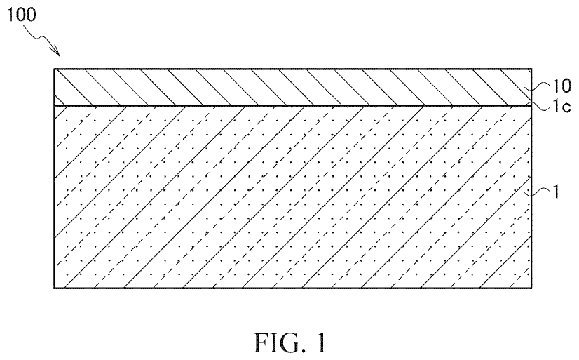

FIG. 1 shows a cross-sectional view of a composite substrate 100 according to the present embodiment.

The composite substrate 100 includes a SiC single crystal substrate 1 and a carbon-containing layer disposed in contact with a surface of the SiC single crystal substrate 1. In this embodiment, the outermost surface of the SiC single crystal substrate 1 is a carbon (C)-terminated surface 1c, and the carbon-containing layer in contact with the C-terminated surface 1c is a graphene layer 10.

The SiC single crystal substrate 1 may have a crystalline structure of either a hexagonal (4H, 6H) crystal or a cubic (3C) crystal. For example, the SiC single crystal substrate 1 containing a hexagonal (4H) crystal is obtained by the following method: sublimating SiC powder as a raw material in a graphite crucible filled with an inert gas such as nitrogen (N₂) gas, and performing recrystallization to obtain a SiC seed crystal under a temperature controlled to be lower than that of the raw material powder (modified from Lely method (seeded sublimation recrystallization method)). At this time, impurities that determine the conductivity type of the SiC single crystal substrate 1 may be added.

The SiC single crystal substrate 1 may also have an off-angle. The “off-angle” in the present disclosure refers to the rotation angle θ when the grown crystal is rotated at a certain angle along the in-plane in the C-axis direction (the direction perpendicular to the substrate plane, the film thickness direction) and cut. The off-angle is preferably between about 0.5° and about 10°, and more preferably between about 4° and about 8°.

The graphene layer 10 has a single layer structure of one layer or a laminated structure of several or more layers. Here, “several layers” means two or more graphene layers 10. From the viewpoint of crystal growth of the epitaxial layer, the number of layer of the graphene layer 10 is preferably between about 1 layer and about 5 layers.

Generally speaking, during the formation of the carbon-containing layer, such as the graphene layer, on the SiC single crystal substrate, by thermal decomposition of the SiC single crystal substrate, the Si atoms of the SiC single crystal substrate are sublimated and the remaining carbons (C) are self-organized, so that the graphene layers will be formed in a stacked manner on the SiC single crystal substrate. By forming the graphene layer using low-temperature processing, the occurrence of step aggregation in the SiC single crystal substrate can be suppressed. However, in order to form the graphene layer with a large number of 6-membered rings and a high crystallinity, high-temperature processing is required.

In this embodiment, in order to form the graphene layer with a highly crystallinity and suppress the occurrence of step aggregation in the SiC single crystal substrate, in addition to supplying carbon from the SiC single crystal substrate as described below, a thin film containing carbon is further deposited on the SiC single crystal substrate to serve as a new source of carbon. A cap film that suppresses thermal decomposition of the SiC single crystal substrate is deposited on the thin film containing carbon, and then the thin film is carbonized by heat treatment to form the carbon-containing layer, such as the graphene layer. Through these steps, the growth of the carbon-containing layer can be promoted before step aggregation of the SiC single crystal substrate occurs.

The surface roughness (Ra) of the SiC single crystal substrate with suppressed step aggregation is small, so the surface roughness (Ra) of the carbon-containing layer formed on the SiC single crystal substrate also becomes small, and the surface where the carbon-containing layer is formed has good flatness. Therefore, the carbon-containing layer with high crystallinity can be formed. In addition, the surface roughness (Ra) can be determined based on JIS B 0601:2013 or ISO 25178, for example.

The surface roughness (Ra) of the carbon-containing layer can be observed with an atomic force microscope. For example, the surface roughness (Ra) of the carbon-containing layer of 2 μm×2 μm is 1.0 nm or less when observed with the atomic force microscope. The surface roughness (Ra) of the carbon-containing layer is preferably 0.7 nm or less, and more preferably 0.5 nm or less.

According to the present embodiment, it is possible to obtain a composite substrate in which the surface roughness (Ra) of the carbon-containing layer formed on the SiC single crystal substrate is reduced.

In the composite substrate 100, the outermost surface of the SiC single crystal substrate 1 is the C-terminated surface 1c, but it is not limited thereto. For example, various modified examples as shown below are also possible.

### Modified Example 1

The structure of a composite substrate 100A according to Modified example 1 will be described. In Modified example 1, the common aspects with the composite substrate 100 shown in FIG. 1 are referred to the above description, and different aspects will be described below.

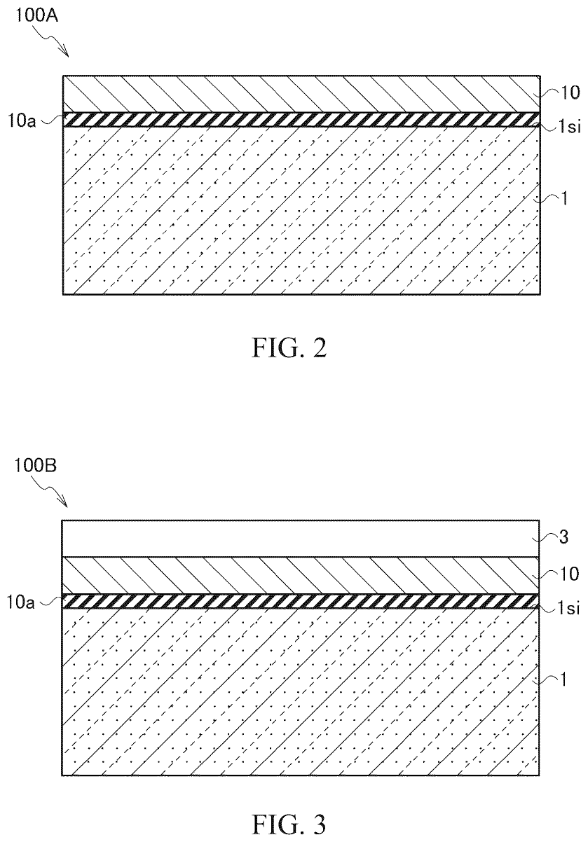

FIG. 2 is a cross-sectional view of the composite substrate 100A of Modified example 1. The composite substrate 100A of Modified example 1 is different from the composite substrate 100 shown in FIG. 1 in the following aspects: the outermost surface of the SiC single crystal substrate 1 is a silicon (Si)-terminated surface 1si, and the carbon-containing layer in contact with the Si-terminated surface 1si is a laminate in which a reconstructed surface layer 10a and the graphene layer 10 are laminated.

In the composite substrate 100A, the outermost surface of the SiC single crystal substrate 1 is the Si-terminated surface 1si. Therefore, when the graphene layer 10 is formed on the surface of the SiC single crystal substrate 1, the reconstructed surface layer 10a is formed on the surface of the SiC single crystal substrate 1, and the graphene layer 10 is formed on the reconstructed surface layer 10a. The reconstructed surface layer 10a plays a role in easing the lattice mismatch with the graphene layer 10, and is also called a buffer layer or layer 0 of the graphene layer.

In Modified example 1, since the step aggregation of the SiC single crystal substrate is also suppressed as described above, the surface roughness (Ra) of the SiC single crystal substrate becomes smaller, and the surface roughness (Ra) of the carbon-containing layer formed on the SiC single crystal substrate also becomes smaller. The surface on which the carbon-containing layer is formed has good flatness, and thus the carbon-containing layer with high crystallinity can be formed.

### Modified Example 2

The structure of the composite substrate 100B according to Modified example 2 will be described. In Modified example 2, the common aspects with the composite substrate 100A shown in FIG. 2 are referred to the above description, and different aspects will be described below.

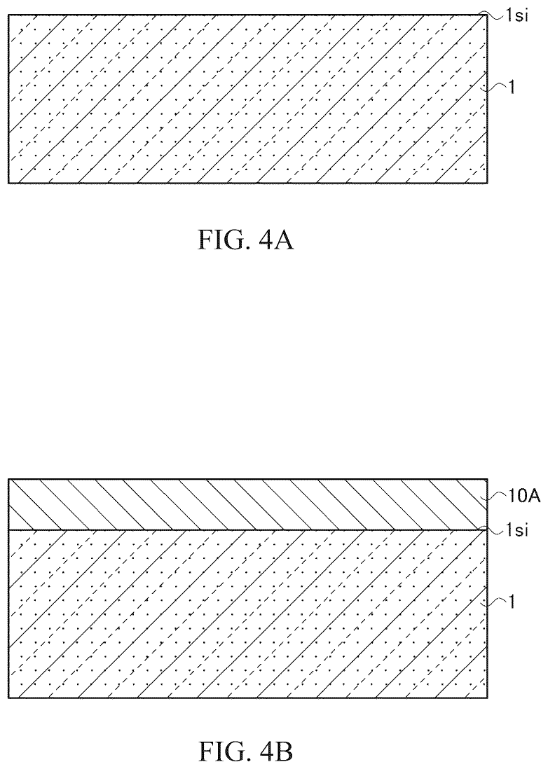

FIG. 3 is a cross-sectional view of a composite substrate 100B according to Modified example 2. The composite substrate 100B of Modified example 2 is different from the composite substrate 100A shown in FIG. 2 in that it includes an epitaxial layer 3 disposed on the graphene layer 10.

In the composite substrate 100B, by using the SiC single crystal substrate 1 having an off-angle, the crystal type of the SiC single crystal substrate 1 is reflected to the crystal growth of the epitaxial layer 3 via the graphene layer 10. Therefore, the epitaxial layer 3 of a single crystal having the same crystal type as that of the single crystal, that is SiC, of the SiC single crystal substrate 1 can be formed. From the viewpoint of crystal growth of the epitaxial layer 3, the off-angle is preferably between about 0.5° and about 10°, and more preferably between about 4° and about 8°.

In addition, from the viewpoint of crystal growth of the epitaxial layer 3, the number of layer of the graphene layer 10 is preferably between about 1 layer and about 5 layers. If the number of layer of the graphene layer 10 is between about 1 layer and about 5 layers, the thickness of the graphene layer 10 itself can be suppressed from increasing, and the crystal type of the SiC single crystal substrate 1 can be reflected to the crystal growth of the epitaxial layer 3.

In Modified example 2, the step aggregation of the SiC single crystal substrate is also suppressed as described above, so the surface roughness (Ra) of the SiC single crystal substrate becomes smaller, and the surface roughness (Ra) of the carbon-containing layer formed on the SiC single crystal substrate becomes smaller as well. Since the surface on which the carbon-containing layer is formed has good flatness, the carbon-containing layer with high crystallinity can be formed.

### (Method of Manufacturing a Composite Substrate)

Next, an example of a method of manufacturing a composite substrate will be described. Here, a method of manufacturing the composite substrate 100B will be described.

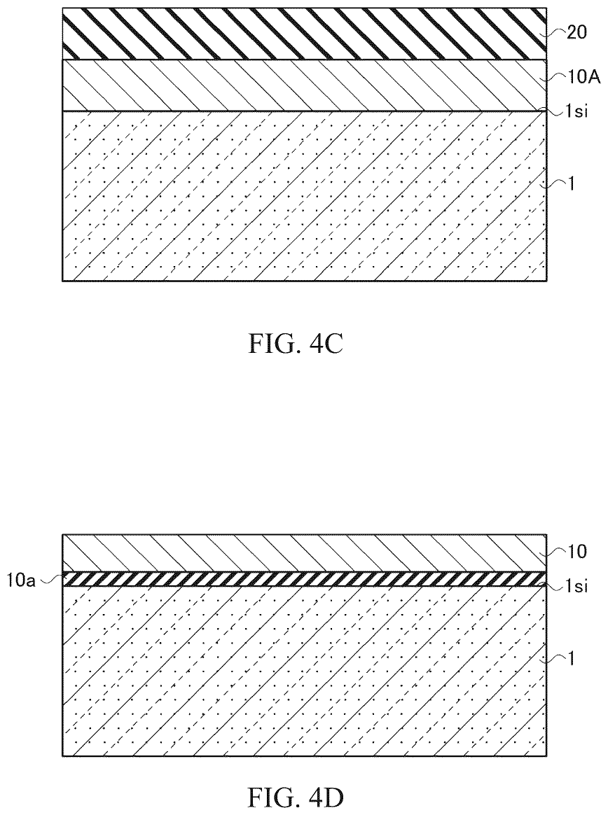

First, as shown in FIG. 4A, hydrofluoric acid is used on the Si-terminated surface 1si of the SiC single crystal substrate 1 to remove the natural oxide film from the SiC single crystal substrate 1. For example, a 4H-SiC substrate having an off-angle of 4° can be used as the SiC single crystal substrate 1. The size of the SiC single crystal substrate 1 is not particularly limited, and for example, a size of 10 mm² can be used.

Next, as shown in FIG. 4B, a thin film 10A containing carbon is deposited on the SiC single crystal substrate 1 from which the natural oxide film has been removed. The deposition method of the thin film 10A is not particularly limited. For example, physical vapor growth method, chemical vapor growth method, wet deposition method, etc. can be used. More specifically, the Langmuir-Blodgett method or the evaporation polymerization method can be used.

Here, stearic acid (C₁₇H₃₅COOH) is dissolved in hexane at a concentration of 1 mM to obtain a dissolution solution, and the SiC single crystal substrate 1 from which the natural oxide film has been removed is immersed in a solution obtained by adding the dissolution solution dropwise into pure water. By pulling up vertically and drying, the SiC single crystal substrate 1 is covered with a monomolecular film. The drying time is, for example, 60 minutes. Furthermore, the SiC single crystal substrate 1 covered with the monomolecular film is placed in a high-frequency induction heating furnace and evacuated. Evacuation can be performed, for example, until it becomes 1×10⁻³ N/m² or less. Then, an inert gas such as argon can be used for flushing, and after reaching atmospheric pressure, the SiC single crystal substrate 1 is heat-treated in an inert gas environment to carbonize the monomolecular film, thereby forming the thin film 10A. The heat treatment temperature is, for example, 400° C.

The thin film 10A functions as a supply source of carbon for forming the carbon-containing layer such as the graphene layer. The thickness of the thin film 10A only needs to be sufficient to function as the supply source of carbon. The thickness of the thin film 10A is, for example, between about 0.3 nm and about 100 nm, between about 1 nm and about 90 nm, or between about 10 nm and about 80 nm.

Next, as shown in FIG. 4C, a cap film 20 that suppresses thermal decomposition of the SiC single crystal substrate 1 is deposited on the thin film 10A. The cap film 20 is configured such that it remains under at least a portion of the temperature range from the temperature at which thermal decomposition of the SiC single crystal substrate 1 starts (for example, from 1200° C. to 1300° C.) up to the temperature at which the graphene layer 10 included in the carbon-containing layer is formed (for example, 1600° C.), with respect to the heat treatment performed in a subsequent step. The cap film 20 is finally removed by heat treatment. The cap film 20 may use a film containing silicon oxide or silicon nitride.

The deposition method of the cap film 20 is not particularly limited. For example, physical vapor growth method, chemical vapor growth method, wet deposition method, etc. may be used. For example, an ECR (Electron Cyclotoron Resonance) plasma CVD (Chemical Vapor Deposition) device capable of film formation at low temperature can be used, and silane can be introduced as a precursor to form a silicon oxide film of 10 nm.

In addition, the thickness of the cap film 20 is configured such that the cap film 20 remains under at least a portion of the temperature range from the temperature at which thermal decomposition of the SiC single crystal substrate 1 starts up to the temperature at which the graphene layer 10 included in the carbon-containing layer is formed, with respect to the heat treatment performed in a subsequent step. The thickness of the cap film 20 may be, for example, between about 1 nm and about 500 nm, between about 10 nm and about 450 nm, or between about 50 nm and about 400 nm.

Next, as shown in FIG. 4D, the SiC single crystal substrate 1 on which the thin film 10A and the cap film 20 are laminated is subjected to heat treatment to remove the cap film 20, and then carbon supplied by the thin film 10A exposed by removing the cap film 20 is used to form a carbon-containing layer in the area where the cap film 20 has been removed on the SiC single crystal substrate 1. The carbon-containing layer includes a laminate, which includes a reconstructed surface layer 10a in contact with the Si-terminated surface of the SiC single crystal substrate 1 and a graphene layer 10 in contact with the reconstructed surface layer 10a.

The heat treatment is performed at a temperature between about 1,200° C. and about 2,500° C., for example. In addition, the heat treatment is performed, for example, in a vacuum environment of 1×10⁴ N/m² or less or in an inert gas environment between about 1×10⁴ N/m² and about 1×10⁶ N/m². An example of the inert gas is argon gas. Here, as the heat treatment, the SiC single crystal substrate 1 on which the thin film 10A and the cap film 20 are laminated is heated at 1600° C. for 5 minutes in a vacuum environment of 1×10⁻⁴ N/m², so that the carbon-containing layer is formed on the surface of the single crystal substrate 1. The temperature rising rate at this time is, for example, 400° C./second.

Next, as shown in FIG. 3, the epitaxial layer 3 is formed on the graphene layer 10 included in the carbon-containing layer. Through the above operations, the composite substrate 100B is completed. The formation (deposition) method of the epitaxial layer 3 is not particularly limited, and for example, physical vapor growth method, chemical vapor growth method, etc. can be used. In addition, the epitaxial layer 3 can be formed at a substrate temperature between about 1,000° C. and about 2,000° C.

The source gas used to form the epitaxial layer 3 is not particularly limited. For example, the volume ratio of propane (C₃H₈) and silane (SiH₄) set to 1:3 can be used. In addition, silane (SiH₄) can be used as the precursor of Si, and propane (C₃H₈) can be used as the precursor of C. Furthermore, argon gas that suppresses etching of the graphene layer 10 may be used as a carrier gas for transporting the source gas.

The thickness of the epitaxial layer 3 is not particularly limited, and may be, for example, 500 nm.

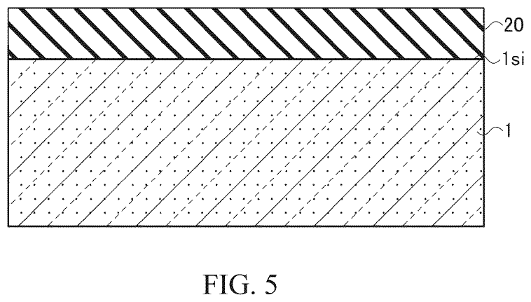

In the method of manufacturing the composite substrate, the thin film 10A that functions as a supply source of carbon for forming a carbon-containing layer such as a graphene layer is used. However, the method is not limited thereto. For example, the cap film 20 may be directly deposited on the SiC single crystal substrate 1 from which the natural oxide film has been removed, as shown in FIG. 5. In this case, the thickness of the cap film 20 is adjusted so that the cap film 20 remains at a required temperature, the cap film 20 is removed through subsequent processing, and then the carbon-containing layer is formed by carbon from the SiC single crystal substrate 1. In addition, in the manufacturing method in which the cap film 20 is directly deposited on the SiC single crystal substrate 1, the supply source of carbon is just the SiC single crystal substrate 1. Therefore, compared with the manufacturing method using the thin film 10A, the coverage speed of the carbon-containing layer slows down.

### Other Embodiments

As mentioned above, several embodiments have been described, but the statements and drawings that form part of the disclosure are illustrative and should not be understood as limiting. Various alternative embodiments, implementations, and operational techniques will be apparent to those skilled in the art from this disclosure. In this way, the embodiments include various embodiments not described here.

### Example of Embodiment

Examples of this embodiment are listed below. This embodiment is not limited to the following example.

### [Note 1]

A method of manufacturing a composite substrate 100, 100A or 100B, comprising:
depositing a cap film 20 on a SiC single crystal substrate 1 to suppress thermal decomposition of the SiC single crystal substrate 1;
performing heat treatment to remove the cap film 20; and
performing heat treatment to form a carbon-containing layer including a laminate of a reconstructed surface layer 10a and a graphene layer 10, or a graphene layer 10 on the SiC single crystal substrate 1, wherein a thickness of the cap film 20 is configured to remain in at least a part of a temperature range from a temperature at which thermal decomposition of the SiC single crystal substrate 1 starts to a temperature at which the graphene layer 10 is formed.

### [Note 2]

The method of manufacturing the composite substrate 100, 100A or 100B of [Note 1], further comprising depositing a thin film 10A containing carbon on the SiC single crystal substrate 1, wherein
the cap film 20 is deposited on the thin film 10A,
during the performing of heat treatment, the cap film 20 is removed and the carbon-containing layer is formed on the SiC single crystal substrate 1 using the carbon supplied from the thin film 10A which is exposed.

According to [Note 1] or [Note 2], the growth of the carbon-containing layer can be promoted before a step bunching of the SiC single crystal substrate occurs, and the composite substrate in which a surface roughness (Ra) of a carbon-containing layer including a highly crystalline graphene layer formed on the SiC single crystal substrate is reduced can be obtained.

### [Note 3]

The method of manufacturing the composite substrate 100, 100A or 100B of [Note 2], wherein the deposition of the thin film 10A is performed by a method selected from a group including physical vapor deposition, chemical vapor deposition and wet deposition.

### [Note 4]

The method of manufacturing the composite substrate 100, 100A or 100B of [Note 2] or [Note 3], wherein the thin film 10A has a thickness between about 0.3 nm and about 100 nm.

According to [Note 3] or [Note 4], the thin film 10A can be used as a carbon supply source for forming a carbon-containing layer such as a graphene layer. A coating speed of the carbon-containing layer can be increased, and a carbon-containing layer can be quickly formed before the step bunching occurs in the SiC single crystal substrate.

### [Note 5]

The method of manufacturing the composite substrate 100, 100A or 100B of any one of [Note 1] to [Note 4], wherein in the heat treatment, after the cap film 20 is removed, the carbon-containing layer is formed in a region of the SiC single crystal substrate 1 from which the cap film 20 has been removed.

### [Note 6]

The method of manufacturing the composite substrate 100, 100A or 100B of any one of [Note 1] to [Note 5], wherein the cap film 20 is a film containing silicon oxide or silicon nitride.

### [Note 7]

The method of manufacturing the composite substrate 100, 100A or 100B of any one of [Note 1] to [Note 6], wherein the deposition of the cap film 20 is performed by a method selected from a group including physical vapor deposition, chemical vapor deposition and wet deposition.

### [Note 8]

The method of manufacturing the composite substrate 100, 100A or 100B of any one of [Note 1] to [Note 7], wherein the cap film 20 has a thickness between about 1 nm and about 500 nm.

### [Note 9]

The method of manufacturing the composite substrate 100, 100A or 100B of any one of [Note 1] to [Note 8], wherein the heat treatment is performed at a temperature between about 1200° C. and about 2500° C.

### [Note 10]

The method of manufacturing the composite substrate 100, 100A or 100B of any one of [Note 1] to [Note 9], wherein the heat treatment is performed in a vacuum atmosphere substantially equal to or less than 1×10⁻⁴ N/m² or in an inert gas atmosphere between about 1×10⁴ N/m² and about 1×10⁶ N/m².

According to [Note 5] to [Note 10], by controlling a configuration of the cap film 20 and heat treatment conditions, the graphene layer 10 included in the carbon-containing layer can be heated from the temperature at which thermal decomposition of the SiC single crystal substrate 1 starts. The cap film 20 is configured to remain in at least a part of the temperature range up to the temperature at which it is formed. Furthermore, a carbon-containing layer can be formed on the SiC single-crystal substrate 1 using carbon supplied from the thin film 10A that is exposed when the cap film 20 is continuously removed.

### [Note 11]

The method of manufacturing the composite substrate 100B of any one of [Note 1] to [Note 10], further including forming an epitaxial layer 3 on the graphene layer 10 included in the carbon-containing layer.

### [Note 12]

The method of manufacturing the composite substrate 100B of [Note 11], wherein a deposition of the epitaxial layer 3 is performed by a method selected from a group including physical vapor deposition and chemical vapor deposition.

### [Note 13]

The method of manufacturing the composite substrate 100B of [Note 11] or [Note 12], wherein the epitaxial layer 3 is formed at a substrate temperature between about 1000° C. and about 2000° C.

According to [Note 11] to [Note 13], the epitaxial layer 3 with small surface roughness (Ra) can be formed, and the epitaxial layer 3 can be easily peeled off from the composite substrate 100B.

### [Note 14]

A composite substrate 100, 100A or 100B, comprising:
a SiC single crystal substrate 1; and
a carbon-containing layer, including a laminate of a reconstructed surface layer 10a and a graphene layer 10 or a graphene layer 10, which is disposed in contact with a surface of the SiC single crystal substrate 1, wherein
when observing by an atomic force microscope, a surface roughness (Ra) of the carbon-containing layer in contact with the SiC single crystal substrate 1 is equal to or less than 1.0 nm in a square area of 2 μm×2 μm.

### [Note 15]

The composite substrate 100A or 100B of [Note 14], wherein the carbon-containing layer includes the laminate, and the reconstructed surface layer 10a of the laminate is in contact with a Si-terminated surface 1si of the SiC single crystal substrate 1.

### [Note 16]

The composite substrate 100, 100A or 100B of [Note 14], wherein the graphene layer 10 included in the carbon-containing layer is in contact with a C-terminated surface 1c of the SiC single crystal substrate 1 or the reconstructed surface layer 10a.

According to [Note 14] to [Note 16], it is possible to obtain a composite substrate in which the surface roughness (Ra) of a carbon-containing layer that is formed on the SiC single crystal substrate and includes a highly crystalline graphene layer is reduced.

### [Note 17]

The composite substrate 100, 100A or 100B of [Note 14], wherein

The composite substrate 100, 100A or 100B of any one of [Note 14] to [Note 16], wherein the SiC single crystal substrate 1 has an off-angle between about 0.5° and about 10°.

### [Note 18]

The composite substrate 100, 100A or 100B of any one of [Note 14] to [Note 17], wherein the SiC single crystal substrate 1 has a crystalline structure of a hexagonal crystal or a cubic crystal.

### [Note 19]

The composite substrate 100, 100A or 100B of any one of [Note 14] to [Note 18], wherein a number of graphene layers 10 included in the carbon-containing layer is between 1 and 5.

### [Note 20]

The composite substrate 100B of any one of [Note 14] to [Note 19], further comprising an epitaxial layer 3 disposed on the graphene layer 10 included in the carbon-containing layer.

According to [Note 17] to [Note 20], the epitaxial layer 3 with small surface roughness (Ra) can be formed, and the epitaxial layer 3 can be easily peeled off from the composite substrate 100B.

1. A method of manufacturing a composite substrate, comprising:
depositing a cap film on a SiC single crystal substrate to suppress thermal decomposition of the SiC single crystal substrate;
performing heat treatment to remove the cap film; and
performing heat treatment to form a carbon-containing layer including a laminate of a reconstructed surface layer and a graphene layer, or a graphene layer on the SiC single crystal substrate, wherein a thickness of the cap film is configured to remain in at least a part of a temperature range from a temperature at which thermal decomposition of the SiC single crystal substrate starts to a temperature at which the graphene layer is formed.

2. The method of claim 1, further comprising depositing a thin film containing carbon on the SiC single crystal substrate, wherein
the cap film is deposited on the thin film,
during the performing of heat treatment, the cap film is removed and the carbon-containing layer is formed on the SiC single crystal substrate using the carbon supplied from the thin film which is exposed.

3. The method of claim 2, wherein the deposition of the thin film is performed by a method selected from a group including physical vapor deposition, chemical vapor deposition and wet deposition.

4. The method of claim 2, wherein the thin film has a thickness between about 0.3 nm and about 100 nm.

5. The method of claim 1, wherein in the heat treatment, after the cap film is removed, the carbon-containing layer is formed in a region of the SiC single crystal substrate from which the cap film has been removed.

6. The method of claim 1, wherein the cap film is a film containing silicon oxide or silicon nitride.

7. The method of claim 1, wherein the deposition of the cap film is performed by a method selected from a group including physical vapor deposition, chemical vapor deposition and wet deposition.

8. The method of claim 1, wherein the cap film has a thickness between about 1 nm and about 500 nm.

9. The method of claim 1, wherein the heat treatment is performed at a temperature between about 1200° C. and about 2500° C.

10. The method of claim 1, wherein the heat treatment is performed
in a vacuum atmosphere substantially equal to or less than 1×10⁻⁴ N/m² or
in an inert gas atmosphere between about 1×10⁴ N/m² and about 1×10⁶ N/m².

11. The method of claim 1, further comprising forming an epitaxial layer on the graphene layer included in the carbon-containing layer.

12. The method of claim 11, wherein a deposition of the epitaxial layer is performed by a method selected from a group including physical vapor deposition and chemical vapor deposition.

13. The method of claim 11, wherein the epitaxial layer is formed at a substrate temperature between about 1000° C. and about 2000° C.

14. A composite substrate, comprising:
a SiC single crystal substrate; and
a carbon-containing layer, including a laminate of a reconstructed surface layer and a graphene layer or a graphene layer, which is disposed in contact with a surface of the SiC single crystal substrate, wherein
when observing by an atomic force microscope, a surface roughness (Ra) of the carbon-containing layer in contact with the SiC single crystal substrate is equal to or less than 1.0 nm in a square area of 2 μm×2 μm.

15. The composite substrate of claim 14, wherein
the carbon-containing layer includes the laminate, and
the reconstructed surface layer of the laminate is in contact with a Si-terminated surface of the SiC single crystal substrate.

16. The composite substrate of claim 14, wherein the graphene layer included in the carbon-containing layer is in contact with a C-terminated surface of the SiC single crystal substrate or the reconstructed surface layer.

17. The composite substrate of claim 14, wherein the SiC single crystal substrate has an off-angle between about 0.5° and about 10°.

18. The composite substrate of claim 14, wherein the SiC single crystal substrate has a crystalline structure of a hexagonal crystal or a cubic crystal.

19. The composite substrate of claim 14, wherein a number of graphene layers included in the carbon-containing layer is between 1 and 5.

20. The composite substrate of claim 14, further comprising an epitaxial layer disposed on the graphene layer included in the carbon-containing layer.
